(19) United States
(12) Patent Application Publication
(10) Pub. No.: US 2022/0385095 A1
(43) Pub. Date: Dec. 1, 2022

(54) Fast Charging Method

(71) Applicant: Bayerische Motoren Werke Aktiengesellschaft, Muenchen (DE)

(72) Inventors: Simon NUERNBERGER, Bad Aibling (DE); Jan Philipp SCHMIDT, Holzmaden (DE)

(21) Appl. No.: 17/770,688

(22) PCT Filed: Sep. 24, 2020
(86) PCT No.: PCT/EP2020/076778

§ 371 Date: Apr. 21, 2022

(30) Foreign Application Priority Data
Oct. 31, 2019 (DE) 10 2019 129 468.1

(51) Int. Cl. H02J 7/00; G01R 31/389

(52) U.S. Cl. CPC H02J 7/007194; G01R 31/389; H02J 7/00309; H02J 7/0048; H02J 7/005; H02J 7/00711

(57) ABSTRACT

A method for fast charging from an initial charge state SOC₀ to a predefined target charge state SOC_{target} is provided. Optimized fast charging conditions are determined using impedance measurements or impedance spectroscopy (EIS) of a battery system which includes a plurality of lithium ion cells. Units consisting of individual cells or of blocks of cells connected in parallel are connected in series, and devices for measuring the voltage and at least one component of the impedance of these cell units are also provided.

### BACKGROUND AND SUMMARY OF THE INVENTION

The present invention relates to a method for the rapid charging of a lithium-ion cell or of a battery system which comprises a plurality of lithium-ion cells, with the aid of impedance measurements or impedance spectroscopy.

For battery systems for automotive applications, in particular for purely electrically operated vehicles, rapid-charging capability presents a particular challenge. In a practical sense, it would be desirable for the charging of the battery system not to last considerably longer than the filling process for a vehicle operated by internal combustion engine.

High charging currents, for example in the range of 2C or more, are required for this. However, such charging currents can lead to intense self-heating and thus to increasing degradation of the electrolyte and accelerated aging of the battery. Furthermore, at high currents, in addition to intercalation there is the risk that metallic lithium is also deposited (Li plating) at the anode, which in turn can lead to internal short circuits.

This is aggravated by the fact that the suitable rapid-charging conditions in turn typically depend on the state of health (SOH) of the cell. It may thus be that certain rapid-charging conditions, which have been optimized based on new cells, lead to problems in cells with a poor SOH.

Rapid-charging strategies for automotive applications up to 350 kW charging power are currently being developed/researched at OEMs and cell manufacturers. Due to a lack of information about the influence of rapid charging on aging and the lack of field data regarding this use case with charging powers up to 350 kW, charging strategies can be designed only very conservatively with a large buffer in order to still function even with the cells advancing in age.

In the current rapid-charging methods of the prior art, the charging conditions are typically adjusted based on the SOC, which in turn is ascertained from the cell voltage (no-load voltage). For example, at a low SOC it is first possible to charge using a constant charging current (CC), the CC charging is continued at a lower charging current when a limit value is exceeded, and charging is continued with a constant voltage (CV) when a further limit value is exceeded until a predetermined target SOC (that is to say a determined target voltage) is achieved. However, cell voltage is not determined by the SOC alone but may also depend on the temperature and the state of health, that is to say the voltage alone is not necessarily a reliable measure for the SOC.

In addition, it is also desirable to specify the rapid-charging conditions depending on the temperature since electrolyte degradation can be facilitated in connection with a high charging current at high temperatures while Li plating can occur at low temperatures. In this case, however, there is the difficulty that the ambient temperature, which is measured for example by a sensor fitted to the housing of the battery system or of the cell, can deviate from the temperature inside the cell. Finally, in particular the influence of the state of health (SOH) should also be taken into account as a limiting factor for the maximum charging current or the maximum charging rate.

In summary, the ideal rapid-charging conditions of a lithium-ion cell depend in particular on the temperature, the SOC or the cell voltage and the SOH. In light of this problem, the task is therefore that of developing a rapid-charging method that takes these dependencies into account and thereby on the one hand enables as short a charging time as possible and on the other hand can prevent premature aging or damage of the cells.

In view of the above problem, an embodiment of the present invention provides a method for the rapid charging of a battery system, in which optimized rapid-charging conditions are ascertained depending on at least one of the cell temperature T, SOC and SOH using impedance measurements or impedance spectroscopy (EIS).

The invention relates in particular to a method for the rapid charging of a battery system which comprises a plurality of lithium-ion cells, wherein units composed of individual cells or of blocks of cells connected in parallel are connected in series, and devices for measuring the voltage and at least one component of the impedance of said cell units are also provided, from an initial state of charge SOC₀ to a predetermined target state of charge SOC_{target},

wherein the method comprises:

continuously or intermittently ascertaining the cell voltages and impedance values of the cell units, wherein the impedance values comprise one or more components of the impedance at one or more frequencies;

determining the state of charge SOC of the battery system from the cell voltage and optionally from the ascertained impedance values;

determining the temperature T_{1 . . . N} of the individual cell units from the ascertained impedance values;

determining the state of health SOH_{1 . . . N} of the individual cell units, state of health comprising at least the capacitance-related state of health SOH_C_{1 . . . N} and preferably also the internal-resistance-related state of health SOH_R_{1 . . . N} determined from the ascertained impedance values;

charging the battery system with a first charging profile P₁, which is selected based on the detected values for SOC₀ and for T_{1 . . . N} and SOH_{1 . . . N}, until a first state of charge limit value SOC₁ is reached or a predetermined maximum temperature Tₘₐₓ is exceeded or a minimum temperature Tₘᵢₙ is undershot in one of the cell units,

charging the battery system with one or more further charging profiles P_{2 . . . M}, which are selected based on the respective detected values for the SOC and for T_{1 . . . N} and SOH_{1 . . . N}, until a corresponding state of charge limit value SOC_{1 . . . N} is reached for the respective charging profile or a predetermined maximum temperature T_{max,2 . . . M} is exceeded or a minimum temperature T_{min,2 . . . M} is undershot in one of the cell units,

until the target state of charge SOC_{target} is reached or the charging process is terminated.

A further aspect of the invention relates to a battery system, which is set up to carry out the rapid-charging method.

### DETAILED DESCRIPTION

### Battery System

The rapid-charging method according to an embodiment of the invention is used to charge a battery system which comprises a plurality of lithium-ion cells. The cells are connected in series in strings individually or in blocks composed of cells connected in parallel in order to provide the overall voltages of 200 to 500 volts that are typically required for use in electrically operated vehicles or (plug-in) hybrid-electric vehicles. A block of individual cells connected in parallel behaves in electrical terms like an individual cell with a correspondingly greater capacitance. In the text which follows, the individual cells or parallel blocks connected in series in the battery system are referred to overall as cell units.

Devices for monitoring the voltage and for measuring at least one component of the impedance are provided for each cell unit, wherein the implementation of these devices is not particularly limited. In one possible embodiment, each cell unit can be provided with a cell supervision circuit (CSC), which is set up at least to measure the voltage. The CSCs are connected in turn to a central battery management unit (BMU). The measured voltage data are advantageously used at the same time to determine the impedance, wherein the impedance can be calculated either in the CSC or in the BMU. In order to prevent excessive loading of the communication channels with the voltage data, it is preferred to use the CSC for calculation.

Furthermore, CSCs can also be used to monitor a plurality of cell units simultaneously, or the monitoring function of all cell units can be integrated into the BMU as a single controller.

The rapid-charging method is typically controlled by way of the BMU taking into account the voltage data and impedance data of the individual cell units. To this end, the BMU is connected to a charger via a suitable data connection, for example a CAN bus, so that the charging current provided or the voltage applied can be regulated accordingly.

The charger that provides the charging current can be fixedly integrated into the battery system or into the vehicle in which the battery system is installed or it is possible to use an external charger which is connected to the battery system only in order to carry out the charging process.

### Impedance Measurement

In the rapid-charging method according to an embodiment of the invention, the impedance measurement or impedance spectroscopy is used in particular for one or more of the following purposes:

determining the cell temperature T; the temperature inside the cell at the respective time can be ascertained directly based on the impedance; temporal inertia effects or spatial averaging over several cells can be prevented as in conventional temperature sensors;

improving the determination of the SOC; conventionally the SOC is determined based on the no-load voltage, which may also depend, however, on the state of health and thus could insufficiently reflect the SOC;

determining the SOH; the impedance spectrum makes it possible to ascertain the electrolyte conductivity and permits conclusions about the kinetics of the Li intercalation/deintercalation at the electrodes; the state of health of the electrolyte and electrodes can be estimated in turn as a result;

determining the Li plating limits; as a result, optimized temperature limit values can be ascertained, upon the undershooting of which the charging current is intended to be reduced or the charging is intended to be interrupted.

In general, the impedance can be measured by virtue of an oscillating current signal (I(t), galvanostatic) or voltage signal (U(t), potentiostatic) being applied to the cell as excitation signal and the corresponding response signal U(t) or I(t) being measured. The impedance can then be calculated as U(t)/I(t) and is generally complex.

In the method according to an embodiment of the invention, a current signal, which by way of example can be impressed on the charging current, is advantageously used as excitation signal and the devices for voltage measurement, which are provided for the individual cell units, are simultaneously used to detect the response signal.

The excitation signal can comprise an individual frequency or a superposition of a plurality of frequencies and it can be applied to the cell continuously or in a pulsed manner. The frequencies are not particularly limited and may be for example in the range from 10 Hz to 10 kHz, advantageously 100 Hz to 5 kHz. In principle, it is sufficient to use a single excitation frequency. As an alternative, two or more excitation frequencies can be used in alternation or in a superposed manner or it is possible to run through a predetermined bandwidth of excitation frequencies in order to record a spectrum. As a further option, the excitation can be carried out in a pulsed manner, for example in the form of a pulse representing a superposition of several frequencies and the measured signal is analyzed by way of Fourier transformation. The spectrum obtained in this way is then correlated with the spectrum of the excitation pulse in order to likewise obtain an impedance spectrum.

In general, the frequency has an influence on the processes in the cell that contribute to the response signal. At high frequencies (for example 1 kHz), the impedance is brought about primarily by the ionic and electronic resistance components in the electrolyte and in the electrodes and arresters, while at low frequencies further contributions are added, which can be attributed to processes with relatively slow timescales such as solid-state diffusion or charge transfer reactions.

In addition, at low frequencies, the dependency on other factors such as in particular the state of charge (SOC) and the state of health (SOH) of the cell also increases. In contrast, at higher frequencies, primarily the influence of the electrolyte resistance, which substantially depends on temperature and the state of health, has an effect.

Due to the different frequency dependency of the influences of temperature, SOC and SOH on the impedance (wherein in addition the influences on the real part or imaginary part can also differ), it is possible, conversely, to ascertain temperature, SOC and SOH through impedance measurement at several different frequencies.

Suitable methods for determining T, SOC and SOH based on the impedance are known in principle in the prior art and can be used for the method according to an embodiment of the invention. DE 10 2013 103 921 thus describes for example cell temperature measurement and degradation measurement in lithium battery systems of electrically operated vehicles through determination of the cell impedance based on an AC voltage signal prescribed by an inverter. The method is based on the observation that the profile of the application of impedance with respect to signal frequency is dependent on temperature.

The Li plating limits can be detected for example by estimating the anode overvoltage when measuring the internal resistance for the determination of the SOH_R.

In one possible embodiment, reference data can be ascertained by virtue of the cell being brought to predetermined temperature (T) and SOC values and the impedance being measured at several frequencies f in order to obtain the impedance as a function of T, SOC and f. It is then possible for example to create a look-up table from the data. When the rapid-charging method according to an embodiment of the invention is carried out, for example the corresponding values for T and SOC can then be read out or interpolated from said table when the measured impedance values are input at the various measurement frequencies. In addition, the change in the data depending on the number of cycles and/or the age of the cell can be examined in order to determine the influence of the SOH.

In this case, further parameters such as in particular cell voltage and housing temperature can preferably additionally be taken into consideration. For example, the cell voltage can be used as an additional input parameter for the SOC, as a result of which the degrees of freedom are reduced and the precision when determining the other parameters such as T and SOH can be improved. The housing temperature can be used for example to test the plausibility of the results; for example a deviation can also be a sign of an anomaly, for example a short circuit that is beginning, which can make further measures such as interrupting the charging process or outputting a warning notification necessary.

In another embodiment, the cell can be modeled by an equivalent circuit diagram having a series resistor Rₛ, which represents the electrolytic resistor, and at least one RC element, possibly supplemented by a Warburg element, for representing the solid-state diffusion in the electrodes, wherein R stands for the transfer resistance and C stands for the capacitance of the charge double layer. The parameters of the equivalent circuit diagram are subsequently ascertained from the impedance measurement values and are correlated with T and also SOC and SOH.

Rₛ thus essentially depends on the temperature and the state of health of the electrolyte. In contrast, R and C depend on the SOC, T and possibly also the state of health of the electrodes, wherein the temperature dependency of those on Rₛ differs, however, and approximately exhibits an Arrhenius response. For the SOC, SOH and T dependency of the parameters of the current circuit diagram, it is possible in turn to establish reference data from which SOC, SOH and T are ascertained when the method according to an embodiment of the invention is carried out, possibly taking into account cell voltage and external temperature.

### Charging Method

The method according to an embodiment of the invention is used for the rapid charging of the battery system from an initial state of charge SOC₀ to a predetermined target state of charge SOC_{target}.

In general, depending on the required external power supply, a distinction is made between AC charging and DC charging. In the case of AC charging, the battery system is provided with a charger (typically <11 kW) integrated into the vehicle, said charger being connected to an AC grid, in order to provide the direct current required to charge the battery system. In the case of DC charging, in contrast, an external charger (>50 kW, up to 350 kW) is used, which provides the charging current. DC charging is mostly used currently for high charging currents as are required for rapid charging. The method according to an embodiment of the invention can be used both in connection with AC and DC charging.

The initial SOC SOC₀ is not particularly limited. In practice, however, rapid charging is considered in particular when the battery system is already substantially discharged and is intended to be charged again as far as possible within a short time, for instance when a “refueling stop” at a charging column has to be made when driving with an electrically operated vehicle, and the journey is subsequently intended to be continued. Therefore, SOC₀ is typically less than 50% of the total capacity, for example approximately 10 to 30%.

In order to prevent premature aging, the target state of charge SOC_{target} is preferably lower than 100% of the total capacity and is for example 60 to 80%. This may be a predetermined maximum SOC for which the battery system is specified with respect to rapid charging. As an alternative, depending on the application, it is possible to prescribe a desired lower target SOC, which has been selected for example in view of the route still to be driven with an electrically operated vehicle. As a further alternative, an available charging time can be prescribed and the target SOC that can be reached in this time is calculated by the battery management system.

The current SOC is determined at least based on the no-load voltage (cell voltage), which is monitored in each cell during charging. The correlation between the SOC and the cell voltage is already known, for example through recording a characteristic curve, and is stored in the battery management system in the form of reference data, with the result that it is possible to derive the SOC from the measured cell voltage.

However, the cell voltage can also depend on other influencing factors, for example temperature (T) and the capacity-related state of health (SOH_C). In the method according to an embodiment of the invention, these additional influences are preferably likewise taken into consideration, for instance by additionally determining the SOC based on the impedance measurement and possible correction of the SOC values determined from the cell voltage. In addition, the SOC reference data can also contain the T-dependency or SOH-dependency. T and SOH can be ascertained based on the impedance measurement used in the method according to an embodiment of the invention and can be included in the ascertaining of the SOC. The SOH is determined here possibly taking into account further SOH-relevant parameters such as in particular the age of the cell, the number of charging cycles and/or the overall amount of energy drawn or charged, which are registered in the battery management system.

The charging profiles P₁ . . . P_{N} may be in particular a charging profile with a constant current (CC) or a charging profile with a constant voltage (CV). In the case of CC charging, the current is kept constant and the voltage increases as the SOC increases, whereas in the case of CV charging the voltage is kept constant and the current decreases as the SOC increases. In addition, a charging profile with a constant power is also possible, in which the product of current and voltage is kept constant. Pulsed charging, in which current pulses, for example as square-wave pulses, followed by a pause, are fed, is likewise considered. The pulses can in turn have a constant current amplitude or a constant voltage.

In the method according to an embodiment of the invention, a CC charging profile is preferably used as first charging profile P₁ and a CV charging profile is preferably used as the last charging profile P₂ or P_{N} before the target SOC is reached. The charging profile can be changed in between, for instance to a further CC charging profile with a reduced charging current, when particular SOC threshold values SOC₁ . . . SOC_{N-1} are reached.

The selected charging current in the charging profiles is typically decreased as the SOC increases, that is to say the current is normally greatest in the first charging profile P₁, wherein the selected value depends at least on the initial SOC and possibly on the temperature and SOH. The charging or discharge current of a battery system is generally specified relative to the capacity of the battery system as what is known as the C-rate, which is defined as the quotient of the maximum current and (nominal) capacity. A C-rate of 1 in a battery system with 1 Ah nominal capacity means for example a charging or discharge over 1 h at a current of 1 A. In the case of rapid charging, charging times of less than 30 minutes, for example approximately 10 to 15 minutes, are desirable, which accordingly corresponds to a theoretical charging current of approximately 2.0 to 6.0 C. However, the initial SOC is typically greater than 0% and the target SOC is lower than 100%, that is to say the charge to be fed is lower than the nominal capacity, such that low charging currents are also considered. On the other hand, the charging current is typically selected depending on the SOC and may be higher initially and may be reduced as the SOC increases. In an initial SOC range of approximately 10-30%, the charging current may therefore be for example 2.0 to 10.0 C, preferably 2.5 to 5.0 C. As the SOC increases, it is then possible to transfer to a lower charging current, for example 1.0 to 5.0 C, preferably 1.5 to 3.0 C for an SOC of 30-50%, and subsequently the current can be further reduced or it is possible to change to a charging profile with a constant power or constant voltage.

Where appropriate, it may be necessary to initially select a charging profile with a lower current for P₁, for instance in order to prevent the risk of Li plating at low temperatures. The cells heat up during charging, with the result that it is possible to change to a charging profile with a greater current when a particular temperature limit value is reached.

In the method according to an embodiment of the invention, the cell temperatures are ascertained for the individual cells from the impedance data in order to adjust the charging profile to the temperature. At excessively high temperatures, for example above 50° C., there is the risk of premature aging while at excessively low temperatures, for example below 10° C., Li plating can occur, in particular in connection with a high charging current.

If the cell temperature exceeds or undershoots a particular temperature limit value Tₘₐₓ or Tₘᵢₙ, it is therefore possible to change to a correspondingly adapted charging profile with a reduced charging current or the rapid charging can be interrupted in order first to bring the cell to the setpoint temperature by cooling or heating. It is also possible to select a plurality of temperature limit values T_{max,1 . . . N} or T_{min,1 . . . N}, wherein in each case there is a successive reduction in the charging current and finally an interruption of the charging process in the case of exceeding and undershooting.

The SOH reflects the state of health of the cell. As the age of the cell increases, both in terms of time and with respect to the number of cycles and the amount of energy converted overall, irreversible degradation processes such as in particular electrolyte decomposition, loss of lithium, degradation of the active material or corrosion effects can occur. These lead to an increase in the internal resistance and to a loss in the usable capacity in comparison to the original nominal capacity. Accordingly, a distinction is made between the capacity-related SOH (SOH_C) and the resistance-related SOH (SOH_R).

The SOH_C can be characterized by the capacity loss, for example as a ratio of the usable capacity to the original nominal capacity. The usable capacity can be determined from the SOC data ascertained by the battery management system in conjunction with the amounts of charge drawn or fed during charging and is stored in the memory of the battery management system for each cell unit and is continuously updated during operation.

The SOH_R reflects the increase in the internal resistance through aging of the electrolyte and can be determined from the impedance data. The determination of the SOH in the method according to an embodiment of the invention at least the determination of the SOH_C, preferably both the SOH_C and the SOH_R. In addition, other criteria such as for example the age of the cell, the number of charging cycles or the amount of energy converted overall can also be included in the determination of the SOH.

In the method according to an embodiment of the invention, charging profiles with a lower charging current are selected for a poor SOH. In addition, the temperature limit values Tₘₐₓ and Tₘᵢₙ at which the charging profile is changed or the charging is interrupted in order to control the temperature of the cell(s) can be stipulated depending on the SOH so that narrower limit values apply for cells with a poor SOH in order to prevent further acceleration of the aging and to prevent possible damage.

The charging profiles P_{1 . . . N} are thus selected at least depending on the SOC of the battery system and on T and SOH of the cell units. However, the selection can also be made taking into account further external conditions, for example a specification for the available charging time. If a sufficient time is available, more conservative charging profiles with a lower charging current can possibly be selected in order to prevent premature aging of the battery system.

In addition, the charging can also be terminated before the target SOC is reached, for instance through user input or also by the battery management system in order to prevent damage, for example upon detection of an abnormal operating state in one of the cells (for example extreme temperature increase) during charging.

1.-9. (canceled)

10. A method for rapid charging of a battery system including a plurality of lithium-ion cells, wherein cell units composed of individual cells or of blocks of cells connected in parallel are connected in series, and devices for measuring a voltage and at least one component of an impedance of the cell units, from an initial state of charge SOC₀ to a predetermined target state of charge SOC_{target}, the method comprising:
continuously or intermittently ascertaining cell voltages and impedance values of the cell units, wherein the impedance values comprise one or more components of the impedance at one or more frequencies;
determining a state of charge of the battery system from the cell voltages;
for each of the cell units, determining a temperature of the cell unit from the impedance values;
for each of the cell units, determining a state of health of the cell unit, wherein the state of health comprises a capacitance-related state of health.
charging the battery system with a first charging profile, which is selected based on detected values for the initial state of charge, the temperatures of the cell units, and the states of health of the cell units, until a first state of charge limit value is reached, a first predetermined maximum temperature is exceeded, or a first predetermined minimum temperature is undershot in one of the cell units; and
charging the battery system with one or more further charging profiles, which are selected based on respective detected values for the state of charge, the temperatures of the cell units, and the states of health of the cell units, until a corresponding state of charge limit value is reached for the respective charging profile, a second predetermined maximum temperature is exceeded, or a second predetermined minimum temperature is undershot in one of the cell units, until the target state of charge is reached or the charging process is terminated.

11. The method according to claim 10, wherein the state of charge of the battery system is determined from the cell voltages and the impedance values.

12. The method according to claim 10, wherein the state of health further comprises the internal-resistance-related state of health determined from the impedance values.

13. The method according to claim 10, wherein the charging profiles are selected from at least one of charging profiles with a constant current, charging profiles with a constant voltage, or charging profiles with a constant power.

14. The method according to claim 10, wherein the charging is performed in a pulsed manner.

15. The method according to claim 10, wherein the initial state of charge is 10-30% of capacity and the first charging profile is a charging profile with a constant charging current in a range from 2.0 to 10.0 C.

16. The method according to claim 10, wherein a last charging profile before the predetermined target state of charge is reached is a charging profile with a constant voltage.

17. The method according to claim 10, wherein the predetermined target state of charge is between 60% and 80%.

18. The method according to claim 10, wherein the impedance values comprise a real part and an imaginary part at at least two different frequencies.

19. The method according to claim 10, further comprising:
interrupting the charging process and temperature control of the battery system to a setpoint temperature when the first predetermined minimum temperature or the second predetermined maximum temperature is exceeded, or the first predetermined minimum temperature or the second predetermined minimum temperature is undershot, before continuing the charging process.

20. A battery system, comprising:
the plurality of cell units;
a signal generator, which is configured to apply an AC signal as an excitation signal to all cells or blocks together, or one or more signal generators for applying the excitation signal to the cells or blocks individually,
at least one of the devices for measuring the voltage for each cell or each block, wherein the at least one of the devices for measuring the voltage is configured to measure an entire cell voltage and an AC voltage component of the cell voltage;
one or more controllers, which are configured to determine the impedance values from the excitation signal and the AC voltage component of the cell voltage; and
a battery management controller for controlling the charging process, wherein the battery management controller is configured to carry out the method according to claim 10.
